(19) United States
(12) Patent Application Publication
(10) Pub. No.: US 2018/0331255 A1
(43) Pub. Date: Nov. 15, 2018

(54) FABRICATION OF ULTRAVIOLET LIGHT EMITTING DIODE WITH TUNNEL JUNCTION

(71) Applicant: X Development LLC, Mountain View, CA (US)

(72) Inventors: Michael Grundmann, San Jose, CA (US); Martin F. Schubert, Mountain View, CA (US)

(21) Appl. No.: 15/970,277

(22) Filed: May 3, 2018

Related U.S. Application Data
(60) Provisional application No. 62/505,717, filed on May 12, 2017.

(51) Int. Cl. H01L 33/06; H01L 33/40; H01L 33/22; H01L 33/32; H01L 33/00

(52) U.S. Cl. CPC H01L 33/06; H01L 33/405; H01L 33/0075; H01L 33/325; H01L 33/0025; H01L 33/22

(57) ABSTRACT

A method of fabricating a light emitting diode (LED) includes forming an active region structured to emit ultraviolet (UV) light and disposed between a first n-type semiconductor region and a first p-type semiconductor region. The method also includes forming a tunnel junction, where the first p-type semiconductor region is disposed between the active region and the tunnel junction, and where the tunnel junction is electrically coupled to inject charge carriers into the active region through the first p-type semiconductor region. A second n-type semiconductor region is also formed, where the tunnel junction is disposed between the second n-type semiconductor region and the first p-type semiconductor region.

### CROSS-REFERENCE TO RELATED APPLICATIONS

This application claims the benefit of U.S. Provisional Application No. 62/505,717, filed May 12, 2017, the contents of which are incorporated herein by reference.

### TECHNICAL FIELD

This disclosure relates generally to light emitting diodes.

### BACKGROUND INFORMATION

Ultraviolet (UV) light loosely refers to electromagnetic radiation with a wavelength of 10 nm to 420 nm, this wavelength range is shorter than that of visible light but longer than X-rays. UV light is emitted from the sun and is approximately 10% of the sun's total output. Light in the UV spectrum can cause chemical reactions in organic molecules; accordingly UV light can cause significant biological effect (most notably sun burn).

Due to UV light's ability to induce chemical reaction and cause materials to fluoresce, UV radiation has a number of applications. For example, light in the ˜10 nm wavelength range may be used for extreme UV lithography, light in the 230-265 nm wavelength range may be used for label tracking and bar codes, and light in the 280-400 nm wavelength range may be used for the medical imaging of cells.

Because UV light has many useful applications, devices that emit UV light are in demand. However, many of these UV sources may suffer from the same deficiencies as conventional light bulbs: they are large, inefficient, fragile, and cannot be used as optical point sources. For example, some common UV emitters are short wavelength fluorescent tube lamps and gas discharge lamps, both of which use an evacuated tube to produce UV light.

### BRIEF DESCRIPTION OF THE DRAWINGS

Non-limiting and non-exhaustive embodiments of the invention are described with reference to the following figures, wherein like reference numerals refer to like parts throughout the various views unless otherwise specified. The drawings are not necessarily to scale, emphasis instead being placed upon illustrating the principles being described.

FIG. 1 is an illustration of an ultraviolet light emitting diode, in accordance with an embodiment of the disclosure.

FIG. 2A is an illustration of a tunnel junction for the ultraviolet light emitting diode in FIG. 1, in accordance with an embodiment of the disclosure.

FIG. 2B is an illustration of a tunnel junction for the ultraviolet light emitting diode in FIG. 1, in accordance with an embodiment of the disclosure.

FIG. 2C is an illustration of a tunnel junction for the ultraviolet light emitting diode in FIG. 1, in accordance with an embodiment of the disclosure.

FIG. 2D is an illustration of a tunnel junction for the ultraviolet light emitting diode in FIG. 1, in accordance with an embodiment of the disclosure.

FIG. 2E is a table showing the processing conditions for the tunnel junction depicted in FIG. 2C, in accordance with an embodiment of the disclosure.

FIG. 3 is an illustration of a tunnel junction and accompanying band diagrams for the ultraviolet light emitting diode in FIG. 1, in accordance with an embodiment of the disclosure.

FIG. 4 illustrates an example flow graph and an example composition v. position graph which show how to achieve enhanced alloy turn-on, in accordance with an embodiment of the disclosure.

FIGS. 5A & 5B an example flow graph and an example composition v. position graph which show how to achieve enhanced alloy turn-on, in accordance with several embodiments of the disclosure.

FIG. 6 illustrates a process for enhanced alloy turn-off, in accordance with an embodiment of the disclosure.

FIG. 7 depicts a method of controlling tunnel junction growth conditions, in accordance with an embodiment of the disclosure.

### DETAILED DESCRIPTION

Embodiments of fabrication for an ultraviolet light emitting diode with a tunnel junction are described herein. In the following description numerous specific details are set forth to provide a thorough understanding of the embodiments. One skilled in the relevant art will recognize, however, that the techniques described herein can be practiced without one or more of the specific details, or with other methods, components, materials, etc. In other instances, well-known structures, materials, or operations are not shown or described in detail to avoid obscuring certain aspects.

Reference throughout this specification to “one embodiment” or “an embodiment” means that a particular feature, structure, or characteristic described in connection with the embodiment is included in at least one embodiment of the present invention. Thus, the appearances of the phrases “in one embodiment” or “in an embodiment” in various places throughout this specification are not necessarily all referring to the same embodiment. Furthermore, the particular features, structures, or characteristics may be combined in any suitable manner in one or more embodiments.

Throughout this disclosure the words “first”, “second”, “third”, etc. are used to refer to different regions of semiconductor materials included in a diode. It is appreciated that these numerical designations are to linguistically differentiate the various regions (which may have the same or similar chemical compositions), describe their position in the device architecture, and maintain proper antecedent basis. Numerical designations of the semiconductor regions may be changed, in accordance with the teachings of the present disclosure.

This disclosure is primarily directed at methods of fabricating a UV emitting light emitting diode (UV LED), which is a highly compact light emitting device.

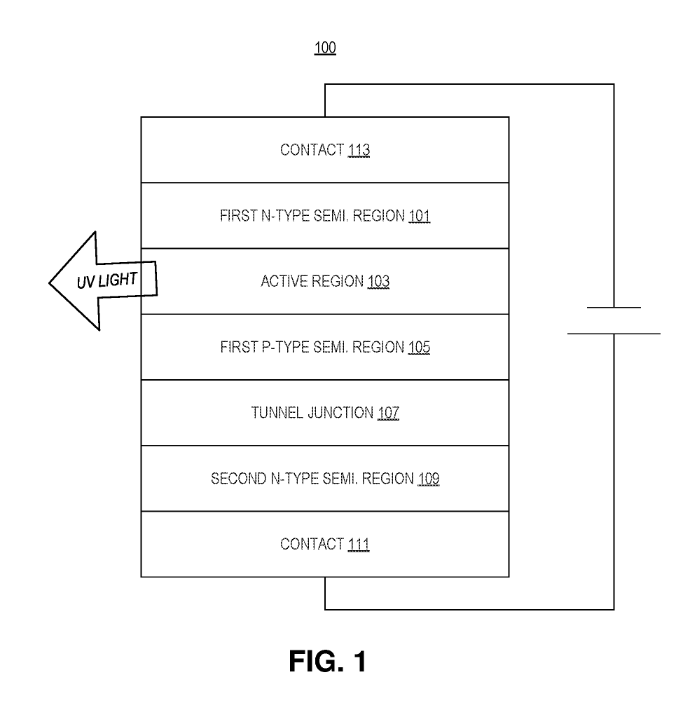

FIG. 1 is an illustration of an ultraviolet (UV) light emitting diode (LED) 100, in accordance with an embodiment of the disclosure. UV LED 100 includes (from top of page to bottom) first contact 113, first n-type semiconductor region 101, active region 103, first p-type semiconductor region 105, tunnel junction 107, second n-type semiconductor region 109, and second contact 111. As depicted, in response to an applied voltage, the active region of UV LED 100 emits UV light. In some embodiments more than 50% of the spectrum emitted by UV LED 100 is UV light. Also, as one of ordinary skill in the art will appreciate, UV LED 100 may emit any other wavelength of light depending on the specific device architecture employed. UV LED 100 may be lasing or non lasing. It is appreciated that the device depicted may be fabricated from the top down (page orientation) or bottom up.

As illustrated, active region 103 is disposed between first n-type semiconductor region 101 and first p-type semiconductor region 105. First p-type semiconductor region 105 is disposed between active region 103 and tunnel junction 107. Tunnel junction 107 is electrically coupled to inject charge carriers into active region 103 through first p-type semiconductor region 105. Tunnel junction 107 is disposed between second n-type semiconductor region 109 and first p-type semiconductor region 105. First electrical contact 113 is coupled to first n-type semiconductor region 101, and second electrical contact 111 is coupled to second n-type semiconductor region 109. UV LED 100 may be formed or grown using any of metal organic chemical vapor deposition, chemical vapor deposition, molecular beam epitaxy or the like.

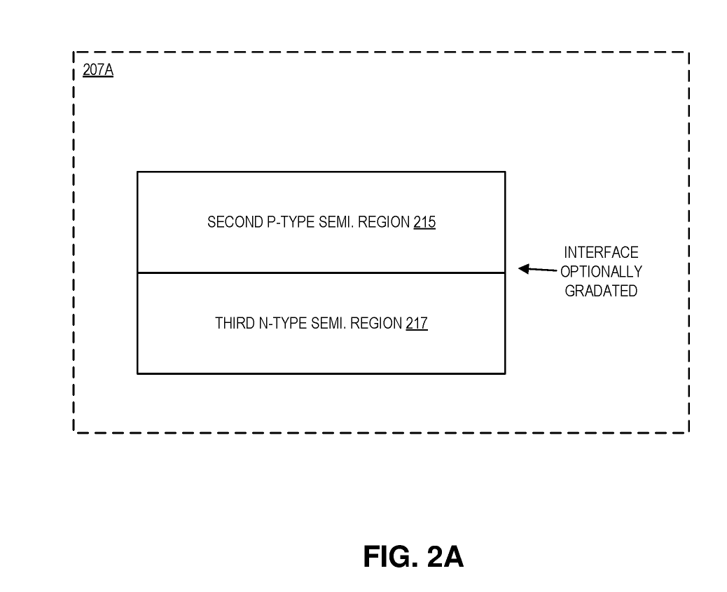

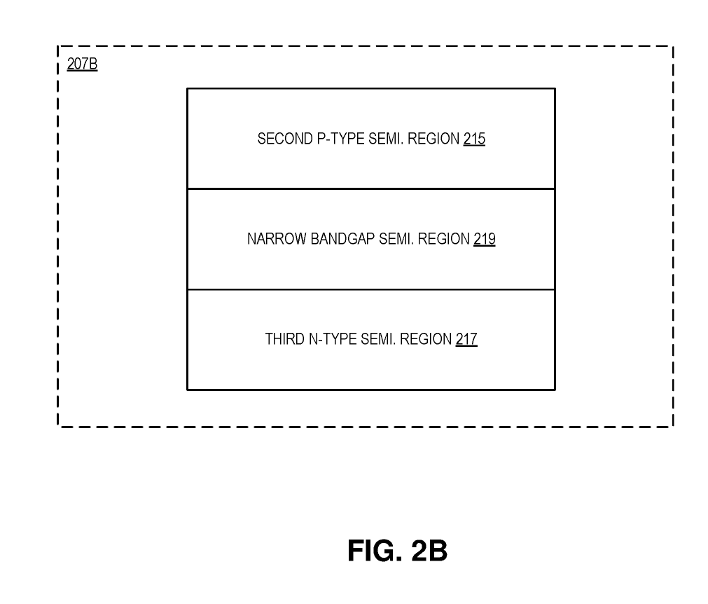

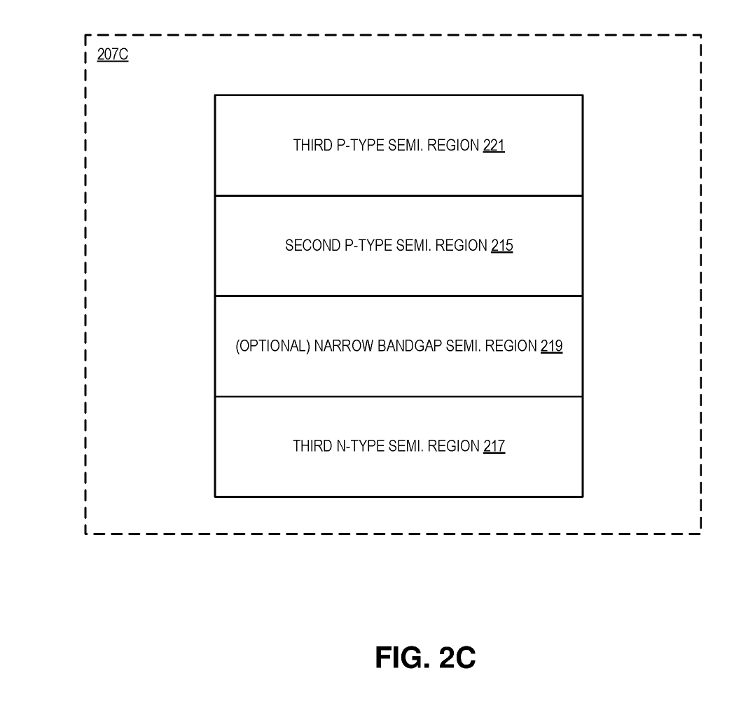

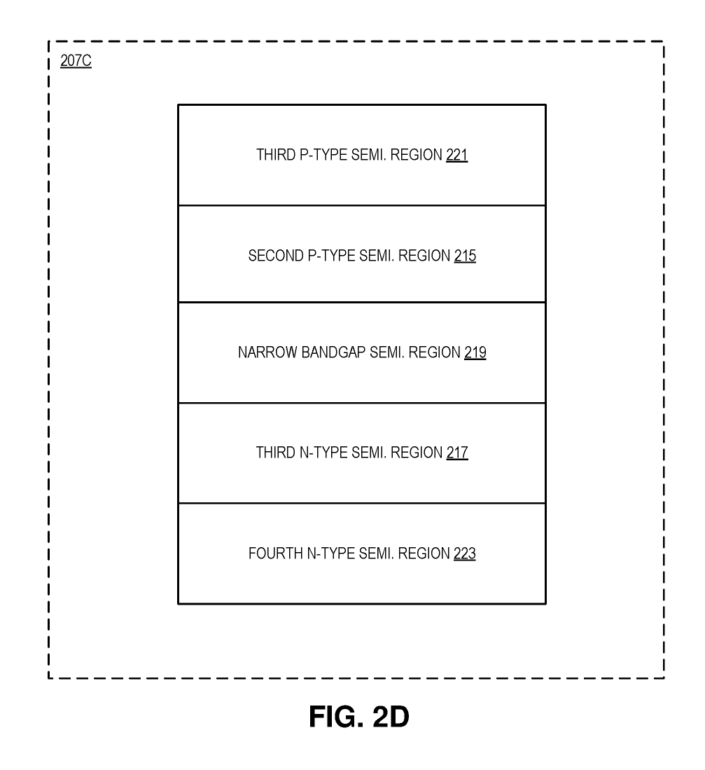

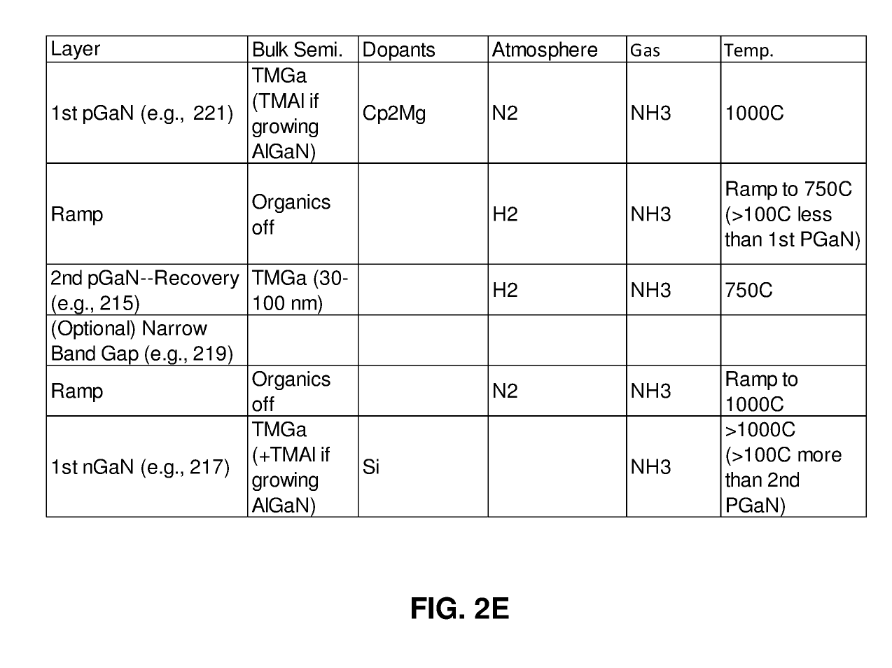

In the depicted embodiment the various components of UV LED 100 may include the following material compositions (among others not discussed to avoid obscuring certain aspects of the disclosure). The composition of tunnel junction 107 will be discussed separately in connection with FIGS. 2A-7.

First n-type semiconductor region 101 may include Al(x)Ga(1-x-y)In(y)N. This semiconductor structure may have a bandgap larger than that of the quantum wells which, in some embodiments, may be incorporated in active region 103. First n-type semiconductor region 101 may also include superlattices, i.e., periodic array of layers with alternating compositions. Further, first n-type semiconductor region 101 may be Si or Ge doped to impart the n-type character.

Active region 103 may include one or more heterostructures composed of Al(x)Ga(1-x-y)In(y)N. The heterostructure may have multiple quantum wells having smaller bandgap regions (smaller Al molar fraction, or alternatively increased In molar fraction), cladded by larger-bandgap barriers (larger Al content) disposed between the individual quantum wells. One of ordinary skill in the art will appreciate the greater the percentage of Al in AlGaInN structures, the larger the bandgap (ranging from ˜7 ev for pure InN and ˜6 eV for AlN). The quantum well count in active region 103 could be 1-10 (or more), and quantum well thickness could range from 1-20 nm. The barrier thickness may range from 1-20 nm. Moreover, active region 103 may also include quantum dots, quantum wires, quantum disks, etc., as active elements embedded in a wide bandgap material.

First p-type semiconductor region 105 may include Al(x)Ga(1-x-y)In(y)N, with a bandgap larger than that of the quantum wells incorporated in active region 103. Similar to first n-type semiconductor region, first p-type semiconductor region 105 may include superlattices. First p-type semiconductor region 105 may also be Mg doped to impart the p-type character.

Lastly, second n-type semiconductor region 109 may include a similar (or the same) structure as first n-type semiconductor region 101 (discussed above). And first contact 113 and second contact 111 may include metals/alloys such as Al, Ti/Al, W/Al, to name a few.

In the depicted embodiment, tunnel junction 107 is used as a “charge conversion layer” to provide holes to UV LED 100. The N layers (101 and 109) are contacted and the tunnel junction is operated in reverse bias to forward bias the PN junction surrounding active region 103. Tunnel junction 107 allows UV LED 100 to be fabricated without contact problems: a p-type contact that is resistive to AlGaN is eliminated, and the contact that replaces it absorbs less light than using a p-type GaN contact layer. In other words, contacting active region 103 with tunnel junction 107 allows for UV LED 100 to be fabricated without (a) an electrode that makes poor electrical contact to the materials in active region 103 or (b) an electrode that absorbs much of the UV light emitted from active region 103. Thus, the device architecture disclosed here represents a meaningful increase in the efficiency of UV emitting LEDs.

FIG. 2A is an illustration of a two layer tunnel junction 207A for the ultraviolet light emitting diode in FIG. 1, in accordance with an embodiment of the disclosure. As depicted tunnel junction 207A includes second p-type semiconductor region 215 (e.g., Al_{0.65}Ga_{0.35}N:Mg; [Mg]˜1e20 cm⁻³) and third n-type semiconductor region 217 (e.g., Al_{0.65}Ga_{0.35}N:Si; [Si]˜1e20 cm⁻³), which may be P+ (e.g., Mg) and N+ (e.g., Si) doped, respectively. In some embodiments, both of these semiconductor materials are degenerately doped to allow charge carriers to tunnel between conduction/valence bands and, under an applied bias, create overlap between empty and full states. Second p-type semiconductor region 215 is disposed between a first p-type semiconductor region (e.g., first p-type semiconductor region 105) and third n-type semiconductor region 217. In some embodiments, the materials in tunnel junction 207A may have a gradated elemental composition. In other words, the transition between second p-type semiconductor region 215 and third n-type semiconductor region 217 occurs gradually. This graded alloy compensation may improve ionization of deep acceptor Mg. Alternatively, tunnel junction 207A may have a step-like composition at the interface of second p-type semiconductor region 215 and third n-type semiconductor region 217 to induce charge (lower Al in third n-type semiconductor region 217 in (0001) oriented layers, for example). In one embodiment, the layers surrounding tunnel junction 207 (e.g., first p-type semiconductor region 105 and second n-type semiconductor region 109 in FIG. 1) may have a wider bandgap than one or both of second p-type semiconductor region 215 and third n-type semiconductor region 217. However, in a different embodiment, the semiconductor materials in tunnel junction 207A may have bandgaps that are wider than, or the same as, the surrounding materials.

One of ordinary skill in the art will appreciate that while second p-type semiconductor region 215 and third n-type semiconductor region 217 are referred to as the “tunnel junction” the actual tunneling of charge carriers occurs in a narrow portion of this structure. Second p-type semiconductor region 215 and third n-type semiconductor region 217 are the semiconductor structures used to facilitate charge carrier tunneling in a small portion of tunnel junction 207A. Tunnel junction 207A includes a potential barrier (i.e., a region where carriers are classically forbidden), where the charge carriers pass through the potential barrier via quantum tunneling. Accordingly, since these structures are used to form the tunneling functionality, this disclosure refers to them collectively as the “tunnel junction”.

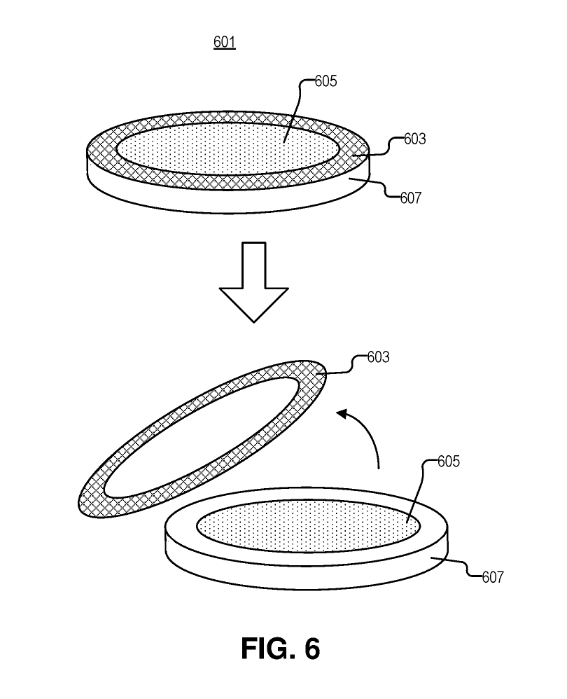

FIG. 2B is an illustration of a three layer tunnel junction 207B for the ultraviolet light emitting diode in FIG. 1, in accordance with an embodiment of the disclosure. Tunnel junction 207B is similar in many respects to tunnel junction 207A; however, tunnel junction 207B includes narrow bandgap semiconductor region 219 (e.g., In_{0.1}Ga_{0.9}N:Mg; [Mg]˜1e18 cm⁻³, see also FIG. 6A) disposed between second p-type semiconductor region 215 (e.g., Al_{0.65}Ga_{0.35}N:Mg; [Mg]˜1e20 cm⁻³) and third n-type semiconductor region 217 (e.g., Al_{0.65}Ga_{0.35}N:Si; [Si]˜1e20 cm⁻³). Narrow bandgap semiconductor region 219 has a narrower bandgap than second p-type semiconductor region 215 and third n-type semiconductor region 217. Narrow bandgap semiconductor region 219 may include, for example, GaN, AlInGaN, InGaN and may be 1-10 nm thick. The structure depicted uses polarization to increase the electric field in tunnel junction 207B. The three-layer tunnel junction 207B includes two layers with substantially the same composition (one p-type, e.g., second p-type semiconductor region 215, and one n-type, e.g., third n-type semiconductor region 217) surrounding a second layer having a different composition (e.g., narrow bandgap semiconductor region 219). Third n-type semiconductor region 217 may be an Mg stopping layer (e.g., an In containing layer to getter, which may contain a different dopant such as Ge). The compositions of second p-type semiconductor region 215/third n-type semiconductor region 217 and narrow bandgap semiconductor region 219 have different polarizations (spontaneous+piezoelectric components). At the 1/2 interface, a sheet charge with magnitude Q=P2−P1 exists, where P2 and P1 are the polarizations of the surrounding materials (second p-type semiconductor region 215/third n-type semiconductor region 217) and the center material (narrow bandgap semiconductor region 219), respectively. At the interface of these materials, the charge is sheet −Q. The thickness of the intermediate layer (d2) should be chosen so that (P2−P1)(d2/eps2)=Eg1/q, where eps2 is the permittivity of the surrounding materials, and Eg1 is the bandgap of the center material. Generally the strong polarization exploited here occurs in the wurtzite phase of the nitrides and the polarization is predominantly electrical.

FIG. 2C is an illustration of a four layer tunnel junction 207C for the ultraviolet light emitting diode in FIG. 1, in accordance with an embodiment of the disclosure. Tunnel junction 207C is similar in many respects to tunnel junction 207B; however, tunnel junction 207C includes third p-type semiconductor region 221 so that second p-type semiconductor region 215 is disposed between third p-type semiconductor region 221 and narrow bandgap semiconductor region 219. However, one of ordinary skill in the art will appreciate that third p-type semiconductor region 221 may be replaced with an n-type semiconductor region (on the other side of the tunnel junction), in accordance with the teachings of the present disclosure. Second p-type semiconductor region 215 may have a higher density of free charge carriers (more heavily doped) than third p-type semiconductor region 221. This four layer structure contemplates an Mg control layer before the polarized layer. In this case the purpose of second p-type semiconductor region 215 is to tailor the profile of Mg in the tunnel junction, and increase the Mg concentration in the immediate vicinity of where tunneling of charge carriers actually occurs. In other words, a magnesium concentration in tunnel junction 207C increases in a direction towards second p-type semiconductor region 215. Alternatively, second P-type semiconductor region 215 may be used as an intermediate hole well in close proximity to the location of charge carrier tunneling.

FIG. 2D is an illustration of a five layer tunnel junction 207D for the ultraviolet light emitting diode in FIG. 1, in accordance with an embodiment of the disclosure. Tunnel junction 207D is similar in many respects to tunnel junction 207C; however, tunnel junction 207D includes fourth n-type semiconductor region 223 so that third n-type semiconductor region 217 is disposed between fourth n-type semiconductor region 223 and narrow bandgap semiconductor region 219. In some embodiments third n-type semiconductor region 217 may have high Si concentrations. In other words, a silicon concentration in the tunnel junction increases in a direction of the third n-type semiconductor region. Generally, high Si concentrations may roughen semiconductor layers, so fourth n-type semiconductor region 223 could be considered a morphology recovery layer. Similar to other embodiments, layers may be graded in composition. Third n-type semiconductor region 217 may also be considered an electron well.

FIG. 2E is a table showing the processing conditions for the tunnel junction depicted in FIG. 2C, in accordance with an embodiment of the disclosure. It is appreciated that the active region (depicted elsewhere) may be formed before or after the tunnel junction.

In the depicted embodiment, the first p-type semiconductor region in the tunnel junction (e.g., third p-type semiconductor region 221 in FIG. 2C) is formed by flowing gallium containing precursor (e.g., trimethylgallium or triethylgallium)—and optionally trimethylaluminum—and bis(cyclopentadienyl)magnesium into a reactor at a first temperature (e.g., ˜1000° C.). The atmosphere of the reactor may include N₂ and NH₃. The semiconductor precursors are then turned off and the reactor is ramped to ˜750° C.

Then, the second p-type semiconductor region in the tunnel junction (e.g., second p-type semiconductor region 215) is formed at ˜750° C. (a second temperature) by flowing the gallium containing precursor into the reactor. It is appreciated that processing temperature may deviate between reactors so ˜750° C. is just one example of the second temperature, more generally, however, the second p-type semiconductor region may be grown at >100° C. less than the first p-type semiconductor region. In one embodiment, this may be a recovery layer to heal defects in the crystal structure from doping. The recovery layer may be 30-100 nm in thickness, and in some embodiments this may be a critical thickness range to sufficiently heal all defects. In the depicted example, the two P-type regions may be fabricated first (despite them being depicted at the top of the page in FIG. 2C).

An optional narrow bandgap semiconductor region (e.g., narrow bandgap semiconductor region 219 in FIG. 2C) is formed on the second p-type semiconductor region. As described elsewhere, the narrow bandgap region may have a smaller bandgap energy than the surrounding device layers.

Next is a ramp to 1000° C. (e.g., >100° C. higher than the temperature used to form the recovery region) with the semiconductor precursors (organics) turned off. The atmosphere of the reactor may include N₂ and NH₃.

After ramping to 1000° C., a first n-type semiconductor region (e.g., third n-type semiconductor region in FIG. 2C) is grown in the tunnel junction. This region may be formed by flowing a gallium containing precursor (e.g., trimethylgallium or triethylgallium) into the reactor along with a silicon containing precursor (e.g., silane or disilane)—and optionally trimethylaluminum—at >1000° C. (a third temperature). As shown, second p-type semiconductor region and the narrow bandgap semiconductor region may be disposed between the first p-type semiconductor region and the first n-type semiconductor region in the tunnel junction. Moreover, the narrow bandgap semiconductor region may have a narrower bandgap than the first p-type semiconductor region and the first n-type semiconductor region in the tunnel junction.

It is appreciated that the depicted first p-type semiconductor region, the second p-type semiconductor region, and the first n-type semiconductor region in the tunnel junction include GaN (which as described may be P-doped, e.g., with Mg, or N-doped e.g., with Si). However, any combination of Al, In, Ga, and N (and other elements) may be used to form any part of the device architecture discussed herein.

Although depicted elsewhere, a first contact and a second contact may be formed to contact the active region and tunnel junction, where the active region and the tunnel junction are disposed between the first contact and the second contact.

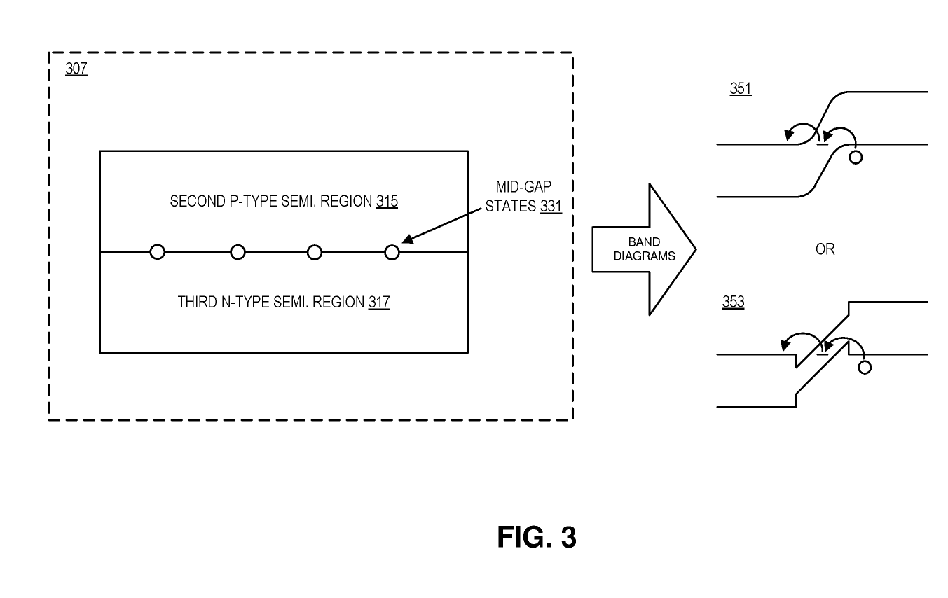

FIG. 3 is an illustration of a tunnel junction 307 and accompanying band diagrams 351/353 for the ultraviolet light emitting diode in FIG. 1, in accordance with an embodiment of the disclosure. In the depicted embodiment, tunnel junction 307 is a two layer tunnel junction (like the tunnel junction depicted in FIG. 2A); however, tunnel junction 307 has mid-gap states 331 disposed between second p-type semiconductor region 315 and third n-type semiconductor region 317. Mid-gap states 331 allow for increased tunneling current at a given bias applied between second p-type semiconductor region 315 and third n-type semiconductor region 317, by providing intermediate states between second p-type semiconductor region 315 and third n-type semiconductor region 317 where charge carriers may dwell. For example, as illustrated in band diagram 351, a mid-gap state 331 is illustrated as an open space in the middle of the p-n junction. Charge carriers can “hop” from one semiconductor material to mid-gap state 331 and then to the other semiconductor material. This increases the overall tunneling probability of electrons in the valence band of second p-type semiconductor region 315 to the empty states in the conduction band of third n-type semiconductor region 317. Band diagram 353 depicts the same phenomenon just with semiconductor materials having a different composition/density of states. In some embodiments, mid-gap states 331 may include at least one of carbon atoms, magnesium atoms, point defects in a semiconductor crystal lattice, or engineered states such as laterally inhomogeneously deposited narrow bandgap material in the form of quantum dots or alternate crystal structures consisting of rare earth atoms. One of ordinary skill in the art will appreciate that this method of potentially improving tunnel junction 307 may be applied to any of the embodiments of the tunnel junction in this disclosure. The position of the layer in the tunnel junction may be adjusted to achieve maximum tunneling current with the minimum bias. For example, for a layer consisting of a state closer to the valence band, the layer may be positioned closer to the nominal p-type bulk layer within the tunneling layer to achieve the highest resonance. The tunneling layer may include multiple types of mid-gap states to further enhance the tunneling current (for example, one layer with a state close to the valence band, one layer with a state close to the conduction band, and one layer with a state in the mid-gap, with each layer spatially separated in the tunneling region).

In the band diagrams 351/353 illustrated, under a reverse bias, the valence band energy of second p-type semiconductor region 315 is greater than or equal to a conduction band energy of third n-type semiconductor region 317. Thus charge carriers jump from the valence band of second p-type semiconductor region 315 into the conduction band of third n-type semiconductor region 317 through the tunnel junction.

The following portions of this document will discuss other methods/techniques used to form the device architectures described above and shown in FIGS. 1-3. One of ordinary skill in the art will appreciate that the methods of fabricating a UV LED described below can be used to form any of the structures disclosed above, and other structures not depicted in FIGS. 1-3. Moreover, the methods may contain other steps not discussed or illustrated, in accordance with the teachings of the present disclosure.

The growth recipes disclosed here dope a nitride-based tunnel junction in a UV LED. In the tunnel junction, a high concentration of Mg may be needed as a p-type layer to pin the valence band on one side of the junction (though other schemes such as polarization-induced band bending may also increase ionization rates that improve Mg effectiveness). The Mg must be sufficiently high concentration and have a sharp enough “turn-on” (i.e., the concentration of dopant as a function of location in the device has a steep—possibly step-like—increase) or “turn-off” (i.e., the concentration of dopant as a function of location in the device has a steep—possibly step-like—decrease) to allow the N-type species on the other side of the tunnel junction to be uncompensated enough to form an effective junction. In other words the location of dopant (or lack of dopant) must be meticulously controlled to realize clearly defined pieces of doped device architecture (not just layers of semiconductor material that blend together). The control of Mg is sometimes challenging in metal organic chemical vapor deposition (MOCVD) reactors because it can form surface layers and coat reactor parts, so the turn-off and turn-on is challenging. Moreover, a surface layer of Mg may exist on the semiconductor material that the Mg is being incorporated into, in order to realize reasonable Mg integration into the crystal. More generally, it can be challenging to get p-type wide-band-gap materials, since the materials tend to be compensated, for example, by integration of hydrogen or other species present in the gas-phase. This is compounded by the high ionization energy for all known p-type dopants in wide-band-gap materials, leading to low ionization of the dopant at normal operating conditions.

The optimization of p-type material/dopant in a tunnel junction (e.g., tunnel junction 107 in FIG. 1, junctions 207 in FIGS. 2A-2D, and junction 307 in FIG. 3) may be different from a bulk material application since the semiconductor layers in a tunnel junction may be very narrow (a few nanometers). This is because with bulk materials, the resistance of the semiconductor is usually optimized. However, in a tunnel junction, the resistance may be a lower priority than the carrier concentration at the tunnel junction interface, so different doping schemes and methods (relative to bulk semiconductor architectures) may need to be used to form an adequate tunnel junction.

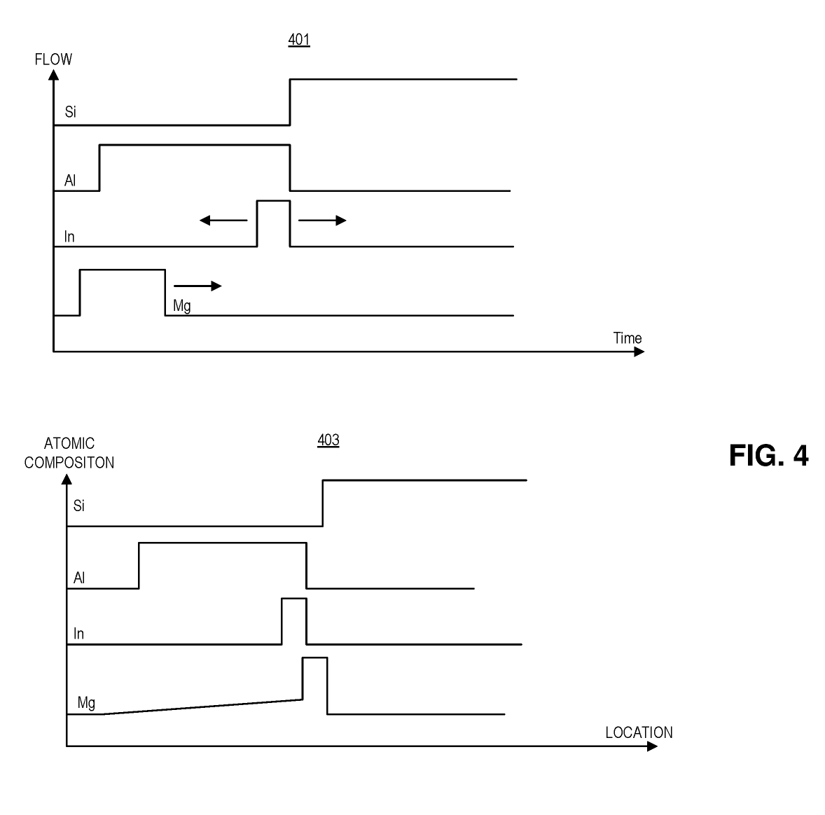

FIG. 4 illustrates an example flow graph 401 and an example composition v. position graph 403 which show how to achieve enhanced alloy turn-on, in accordance with an embodiment of the disclosure. The following process will be discussed with reference to the tunnel junction in FIG. 2A but one of ordinary skill in the art will appreciate that the process is applicable to any of the other device architectures depicted.

Flow graph 401 depicts precursors of the elements listed (i.e., Si, Al, In, and Mg) being flowed into the reaction chamber to form the tunnel junction (e.g., tunnel junction 207A). One of ordinary skill in the art will appreciate that other precursors (e.g., precursor compounds containing Ga, Ge, N, or the like) and gasses (e.g. N₂, H₂, Ar or the like) may be flowed into the reactor at the same time as the species depicted, but are not illustrated to avoid obscuring certain aspects. As depicted, at the start of the process an aluminum containing species (e.g., AlGaN) is being grown. Then, a magnesium source (e.g., bis(cyclopentadienyl)magnesium [abbreviated Cp₂Mg]) is turned on to grow a p-doped region (e.g., second P-type semiconductor region 215). After the magnesium is turned on, the indium precursor (e.g., trimethylindium [abbreviated TMIn]) is introduced into the reactor. The deposited In may lower the incorporation energy of the Mg into the GaN/AlGaN semiconductor crystal. This enhanced incorporation produces a sharp Mg peak at the location of the In (see e.g., position graph 403 where the Mg and In concentrations are aligned and clearly defined at the junction interface). After the Mg is incorporated into the semiconductor crystal, an n-type dopant (e.g., Si) is introduced to the reactor to produce an n-doped region (e.g., third N-type semiconductor region 217).

Introduction of the indium precursor into an MOCVD reactor is known to getter residual Mg. Mg rides the surface of GaN normally, but either the presence of In, or the heterointerface between (Al)GaN and InGaN, can permit a marked increase in Mg incorporation into the semiconductor crystal since In lowers the energy required for Mg to incorporate into the crystal. Since Mg is riding the surface, it may be possible to have a large amount of nonincorporated Mg on the crystal surface during bulk growth, then when TMIn is switched on, the Mg content of the semiconductor crystal may increase. Alternatively, the Al precursor may be turned off and a large increase in Mg in the crystal may be expected. Indium similarly “rides” the surface but may be removed by Cl flow.

In one embodiment, the TMIn could be pulsed to make many heterointerfaces that may capture more Mg. Alternatively or additionally, the Al may be turned off in a pulsed mode, forming an AlGaN/GaN superlattice with increased Mg.

In another embodiment, a pause may be used before turning on the indium or after turning off the Al to further enhance the Mg incorporation effect. During the pause, NH₃ and ambient gases may still be flowing, but metalorganics are turned off. However, in some embodiments, Cp₂Mg may be left on.

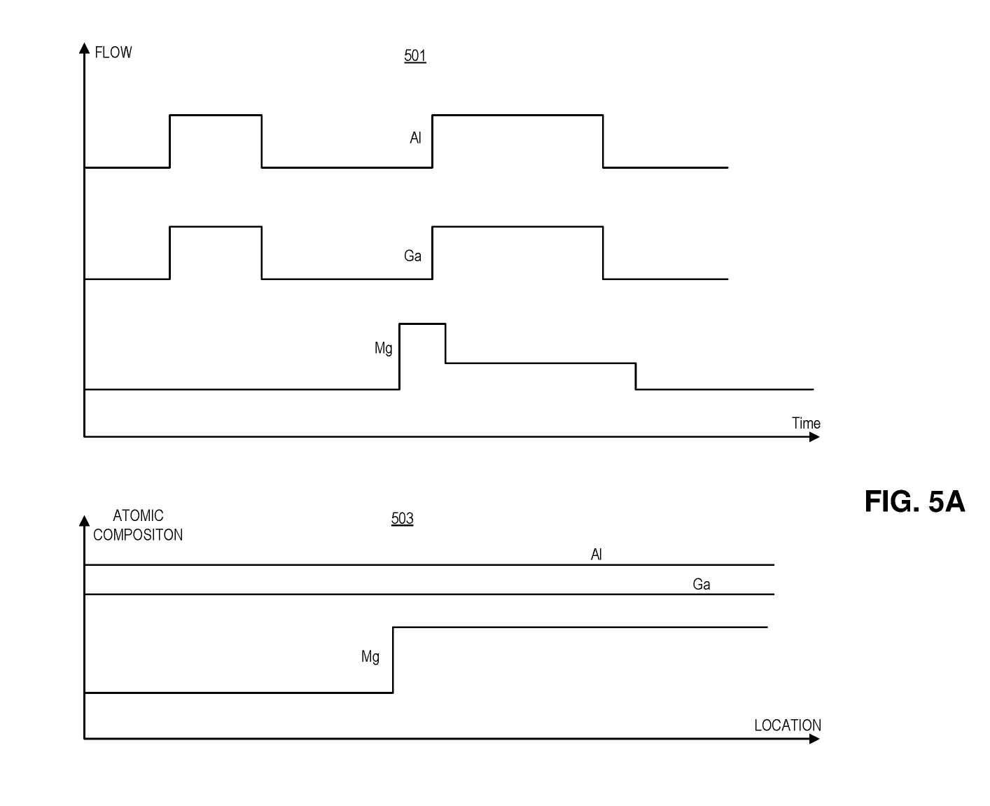

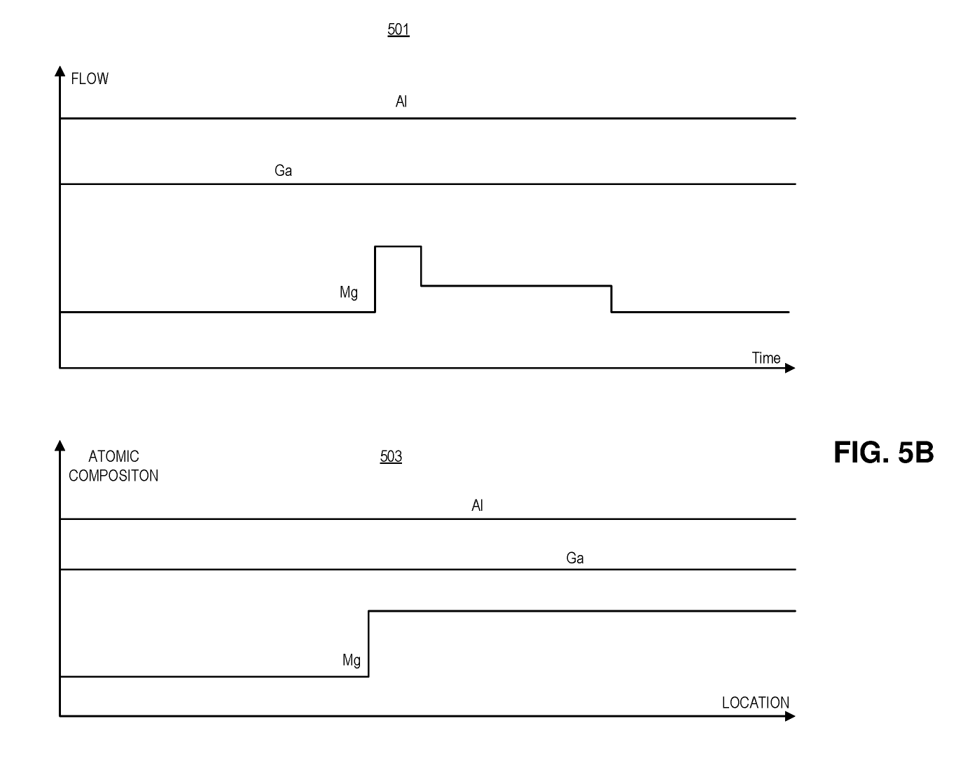

FIG. 5A illustrates an example flow graph 501 and an example composition v. position graph 503 which show how to achieve enhanced alloy control for turn-on, in accordance with an embodiment of the disclosure. More specifically the graphs depict how to use an Mg preflow to improve turn-on. The following process will be discussed with reference to the tunnel junction in FIG. 2A but one of ordinary skill in the art will appreciate that the process is applicable to any of the other device architectures depicted.

Flow graph 501 depicts precursors of the elements listed (i.e., Si, Al, In, and Mg), and other not listed (e.g., N precursor), being flowed into the reaction chamber to form the tunnel junction (e.g., tunnel junction 207A). In this scheme, the Al and Ga precursors (more generally group III precursors) are turned off for a period, and then only the Mg precursor, Cp₂Mg, is allowed to flow into the reactor with the alkyl and carry gasses (e.g., NH₃, N₂, H₂, Ar). This is to “precoat” the surface of the semiconductor with Mg to sharpen the turn-on of Mg in a p-type region (e.g., second p-type semiconductor region 215) of the tunnel junction. Combined with compositional changes of the alloy after the paused growth, Mg density may be increased in the final crystal (as shown with the sharp Mg turn-on in graph 503).

FIG. 5B illustrates an example flow graph 501 and an example composition v. position graph 503 which show how to achieve enhanced alloy control for turn-on. Similarly to FIG. 5A, the graphs depict how to use an Mg preflow to improve turn-on. Instead of a pause (like in FIG. 5A), the Cp₂Mg may be momentarily increased to very high levels (see e.g. high level of Mg in graph 501 while Al and Ge are flowing at constant rates) with the intention of saturating the semiconductor crystal surface. This high turn-on level results in a step-like increase in the Mg concentration in the tunnel junction (e.g., to form second P-type semiconductor region 215 of FIG. 2A). Then, as depicted in graph 501, the flow of Mg precursor is brought down to a lower level after the surface of the semiconductor is saturated with Mg.

It is suspected that a wetting layer of liquid Mg forms on the semiconductor crystal surface, and that before the Mg is incorporated into the underlying GaN/AlGaN crystal, the Mg surface layer needs to achieve a certain concentration. Here, the high initial flow rate of Mg precursor causes the surface to saturate quickly creating the sharp Mg turn-on.

FIG. 6 illustrates a process for alloy turn-off, in accordance with an embodiment of the disclosure. More specifically, FIG. 6 and associated discussion contemplates ways to form a clearly defined stopping point for an Mg rich layer (e.g., second P-type semiconductor region 215 of FIG. 2A) in a tunnel junction.

Often significant amounts of Mg come from surrounding reactor parts. This is from Mg being deposited on the reactor parts as a byproduct of forming device architecture. Mg can be redeposited from the reactor parts to the wafer during subsequent deposition steps, which can cause undesirable results. As shown, these parts may be swapped out (especially the parts that get coated) during a partial cooldown of the reactor to provide clean parts. This could be accomplished by using an additional thin quartz top layer (baffle 603) surrounding the wafers 605, and on top of wafer holder 607, that could be removed (e.g., robotically) after the Mg containing layers are deposited without completely cooling the reactor. The removable quartz baffle 603 may allow for the high temperature baking of reactor parts with the wafers still in the reactor. Having a removable baffle 603 prevents Mg that was deposited on baffle 603 from being redeposited on the wafer 605 in subsequent processing steps (since baffle 603 is removed post Mg deposition).

In another or the same embodiment, semiconductor crystal growth may be stopped by interrupting the flow of metalorganics and using thermal desorption to remove residual Mg. In other words, the after the Mg is used to dope the semiconductor crystal (e.g., forming second P-type semiconductor region 215), residual Mg may be “burned off” by heating the wafer, thus preventing residual Mg from bleeding into other layers of device architecture.

In another or the same embodiment, Mg may be controlled by stopping growth and performing an in situ etch (e.g., using Cl₂). This method stops the growth, or alternatively, supplies enough Ga, Al, and In to keep the surface at equilibrium, and introducing another species of chemical into the reaction chamber to chemically remove Mg. Cl₂ is one example, but NH₃ might be used to polymerize and remove Mg. H₂ alone might be sufficient to remove Mg as well, or if H is introduced as an atom (via plasma for example) to create a hydride of Mg, then the Mg hydride could be etched away using another chemical, such as H₂O, for example.

In another example, growth of Mg doped crystal may be stopped using an In(GaAl)N cap, removing the sample (optional), changing the reactor parts, sublimating (or etching) the cap, and then continuing to fabricate the other tunnel junction layers. Similarly, Mg doped crystal growth may be stopped with a sacrificial (Al)GaN cap, removing the sample (optional), changing the reactor parts, sublimating or etching the cap (e.g., using H₂), and continuing to fabricate the other tunnel junction layers. Both of these schemes cap the wafer with a protective sacrificial layer after the Mg containing layers are deposited. After the sacrificial (In)(Al)GaN is grown, the wafers are removed, the reactor parts are removed or cleaned in situ, then the wafers are reintroduced to the reactor and the cap layer is either etched back chemically, or thermally desorbed, to expose the desired interface. After removal of the cap, the rest of the tunnel junction is grown. Alternatively, all reactor parts may be left in, then the reactor parts may be preferentially cooled during the etch process so that the etch occurs faster on the wafer. Then the Mg is buried in the reactor parts, and the tunnel junction surface is left exposed on the wafer and ready for subsequent growth. The Mg control process may be monitored using external differentially pumped residual gas analyzer which enables an etch stop layer that may include a high In content or other species, or alternatively this process may be monitored using reflectance techniques. A simple implementation of this is to remove the sample without a cap, etch the wafer in aqua regia or other acid like HCl, introduce clean parts into the reactor, then proceed with the N-type growth (e.g., third N-type semiconductor region 217).

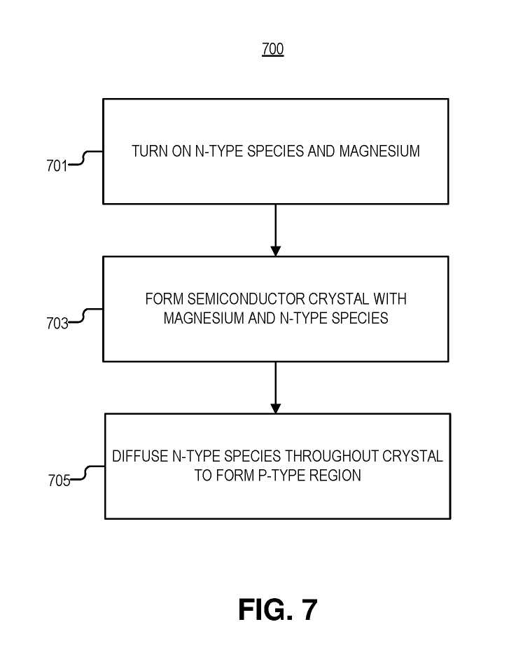

FIG. 7 depicts a method of controlling tunnel junction growth conditions, in accordance with an embodiment of the disclosure. One of ordinary skill in the art will appreciate that the blocks in method 700 are not limiting: additional blocks may be added to method 700, blocks may be removed from method 700, and the blocks depicted may occur in a variety of orders.

Block 701 shows turning on Mg and N-type (e.g., Ge) sources simultaneously. Block 703 illustrates forming a semiconductor crystal with both Mg and Ge (or other highly-mobile N-type species, e.g., H or Si). Block 705 depicts thermally annealing the semiconductor material to diffuse the n-type species throughout a large volume of semiconductor crystal. Thus, the P-type character of Mg becomes the majority charge carrier type in the region of the crystal where the Mg was deposited, since Mg is not highly mobile. The codoping with a highly mobile N-type species reduces the formation energy of the active MgH site as the fermi level tends toward the conduction band. If Ge or other N-type dopants are deposited, it might be possible to further increase the Mg concentration at the surface by codoping with that species and using a similar ex situ treatment, such as a thermal anneal.

In another or the same embodiment The NH₃ flow and temperature of the substrate are normally optimized to give the best sheet resistance of the p-type material. In a tunnel junction, the charge density is the primary design concern. Therefore, both the V/III ratio and temperature may be optimized near the junction to provide the highest charge density while the mobility may be low (relative to other semiconductor layers in the LED—for example the semiconductor layers surrounding the tunnel junction). There are some indications that, in general, the charge may increase with increased V/III ratio and/or decreased growth temperature for GaN.

The above description of illustrated embodiments of the invention, including what is described in the Abstract, is not intended to be exhaustive or to limit the invention to the precise forms disclosed. While specific embodiments of, and examples for, the invention are described herein for illustrative purposes, various modifications are possible within the scope of the invention, as those skilled in the relevant art will recognize.

These modifications can be made to the invention in light of the above detailed description. The terms used in the following claims should not be construed to limit the invention to the specific embodiments disclosed in the specification. Rather, the scope of the invention is to be determined entirely by the following claims, which are to be construed in accordance with established doctrines of claim interpretation.

What is claimed is:

1. A method of fabricating a light emitting diode (LED), comprising:
forming an active region structured to emit ultraviolet (UV) light disposed between a first n-type semiconductor region and a first p-type semiconductor region;
forming a tunnel junction, wherein the first p-type semiconductor region is disposed between the active region and the tunnel junction, and wherein the tunnel junction is electrically coupled to inject charge carriers into the active region through the first p-type semiconductor region; and
forming a second n-type semiconductor region, wherein the tunnel junction is disposed between the second n-type semiconductor region and the first p-type semiconductor region.

2. The method of claim 1, wherein forming the tunnel junction includes:
growing a second p-type semiconductor region using a reactor; and
growing a third n-type semiconductor region, wherein the second p-type semiconductor region is disposed between the first p-type semiconductor region and the third n-type semiconductor region.

3. The method of claim 2, further comprising growing a narrow bandgap semiconductor region disposed between the second p-type semiconductor region and the third n-type semiconductor region, wherein the narrow bandgap semiconductor region has a narrower bandgap than the second p-type semiconductor region and the third n-type semiconductor region.

4. The method of claim 2, further comprising growing a third p-type semiconductor region, wherein the second p-type semiconductor region is disposed between the third p-type semiconductor region and the third n-type region.

5. The method of claim 4, wherein the second p-type semiconductor region is a recovery region.

6. The method of claim 4, wherein the second p-type semiconductor region, the third p-type semiconductor region, and the third n-type semiconductor region include GaN.

7. The method of claim 6, wherein growing the third p-type semiconductor region includes flowing a gallium containing precursor and bis(cyclopentadienyl)magnesium into a reactor at a first temperature.

8. The method of claim 6, wherein growing the third n-type semiconductor region includes flowing the gallium containing precursor and a silicon containing precursor into the reactor.

9. The method of claim 8, wherein the gallium containing precursor and the silicon containing precursor are flowed into the reactor at a second temperature which is greater than or equal to the first temperature

10. The LED of claim 1, wherein the tunnel junction includes a potential barrier, and wherein the charge carriers pass through the potential barrier via quantum tunneling.

11. A method of fabricating a light emitting diode (LED) to emit ultraviolet (UV) light, comprising:
forming an active region including one or more quantum wells structured to emit the UV light; and
forming a tunnel junction, electrically coupled to the active region to inject charge carriers into the active region to emit the UV light, wherein the tunnel junction includes a potential barrier and the charge carriers pass through the potential barrier via quantum tunneling.

12. The method of claim 11, wherein forming the tunnel junction includes:
growing a first p-type semiconductor region; and
growing a first n-type semiconductor region.

13. The method of claim 12, wherein forming the tunnel junction further includes:
growing a second p-type semiconductor region disposed between the first p-type semiconductor region and the first n-type semiconductor region, wherein the second p-type semiconductor region is a recovery region.

14. The method of claim 13, wherein the first p-type semiconductor region, the second p-type semiconductor region, and the first n-type semiconductor region include GaN.

15. The method of claim 14, wherein growing the a first p-type semiconductor region includes flowing a gallium containing precursor and bis(cyclopentadienyl)magnesium into a reactor at a first temperature.

16. The method of claim 15, wherein growing the second p-type semiconductor region includes flowing the gallium containing precursor into the reactor at a second temperature that is lower than the first temperature.

17. The method of claim 15, wherein growing the first n-type semiconductor region includes flowing the gallium containing precursor and a silicon containing precursor into the reactor.

18. The method of claim 17, wherein the gallium containing precursor and the silicon containing precursor are flowed into the reactor at a third temperature which is greater than or equal to the first temperature.

19. The method of claim 12, wherein forming the tunnel junction further includes:
growing a narrow bandgap semiconductor region disposed between the first p-type semiconductor region and the first n-type semiconductor region, wherein the narrow bandgap semiconductor region has a narrower bandgap than the first p-type semiconductor region and the first n-type semiconductor region.

20. The method of claim 1, further comprising:
forming a first contact; and
forming a second contact, wherein the active region and the tunnel junction are disposed between the first contact and the second contact.
